(19) United States
(12) Patent Application Publication
(10) Pub. No.: US 2003/0119296 A1
(43) Pub. Date: Jun. 26, 2003

(54) Semiconductor device and manufacturing method for the same

(76) Inventors: Jun Tsukano, Kanagawa (JP); Tomoko Takizawa, Kanagawa (JP); Takehiko Maeda, Kanagawa (JP)

Correspondence Address: KATTEN MUCHIN ZAVIS ROSENMAN, 575 MADISON AVENUE, NEW YORK, NY, 10022-2585, US

(21) Appl. No.: 10/328,260

(22) Filed: Dec. 23, 2002

(30) Foreign Application Priority Data
Dec. 26, 2001 (JP) 2001-395231

(51) Int. Cl. H01L 21/44; H01L 21/48; H01L 21/50; H01L 23/48; H01L 23/52; H01L 29/40

(52) U.S. Cl. 438/612; 438/117; 257/737

(57) ABSTRACT

Concave portions having shapes adapted to the remaining resist are formed in the vicinities of external terminals of metal wiring. The external terminals of the metal wiring project from the side surfaces of the concave portions. By thus constructing the external terminals, no matter which of the X, Y, and Z directions solder balls that are connected to lands displace in, the lands can displace by following the displacement of the solder balls without restriction. Therefore, even when the semiconductor device and a mounting substrate have elongation differently from each other due to a difference in the coefficient of thermal expansion, the elongation can be absorbed.

### BACKGROUND OF THE INVENTION

1. Technical Field of the Invention

The present invention relates to a semiconductor device and a manufacturing method for the same. More specifically, the invention relates to a semiconductor device to be electrically connected to a mounting substrate by solder balls, in which a force to act on the solder balls caused by a difference in the coefficient of thermal expansion between the semiconductor device and the mounting substrate can be absorbed by displacement of a wiring metal, and a manufacturing method for the same.

2. Description of the Related Art

FIG. 1A through FIG. 1G are sectional views showing a conventional semiconductor device manufacturing method in an order of steps. As shown in FIG. 1A and FIG. 1B, when metal wiring is formed on a base metal 610, a resist 612 is applied in a pattern opposite to the wiring pattern. Thereafter, as shown in FIG. 1C, plating of wiring metal 614 is applied into grooves formed by the resist. After plating, as shown in FIG. 1D, the resist 612 is removed by a solvent. In this condition, wiring is left on the base metal.

Thereafter, an insulating resin 624 is poured between the surface of the base metal and the back surface of the semiconductor element while electrical conduction is made between the electrode pad of the semiconductor element 622 and the wiring 614 via metal bumps 620. After solidification of the insulating resin 624, the semiconductor device is resin-sealed so that the semiconductor device at the base metal 610 surface side is covered. Then, the base metal 610 is removed by chemical etching. Thereafter, a solder resist is printed while leaving out external terminals for a mounting substrate, whereby the wiring is covered by the solder resist. In the semiconductor device manufactured by the above-mentioned method, external terminals of the wiring are exposed at the back surface. The external terminals and a mounting substrate are electrically connected by solder balls 626.

However, materials of the semiconductor device and the mounting substrate are different from each other. Therefore, among the physical properties of these materials, the coefficients of thermal expansion are also different from each other. When the semiconductor device and the mounting substrate are exposed to heat with the semiconductor device mounted on the mounting substrate, the semiconductor device and the mounting substrate also become different in elongation from each other.

The objects to which the semiconductor device and the mounting substrate are electrically connected are the solder balls 626. The semiconductor device and the mounting substrate are located at fixed positions, and therefore, the wiring 614 is also restricted by the semiconductor device. Likewise, the wiring of the mounting substrate is also restricted. Therefore, the difference in elongation causes a shearing force or moment at the connecting positions between the solder balls 626 and the semiconductor device and mounting substrate. Due to this shearing force, the connection between the solder ball 626 and the semiconductor device and the connection between the solder ball and the mounting substrate become easily breakable as a result of cracks and separation. If the connection is broken, a conduction failure occurs between the semiconductor device and the mounting substrate.

Thus, in some cases, the conventional semiconductor manufacturing method and structure lose their reliability.

### SUMMARY OF THE INVENTION

The object of the present invention is to provide a semiconductor device and a manufacturing method for the same, wherein even when a semiconductor device and a mounting substrate is different in elongation from each other due to a difference in the coefficient of thermal expansion, the elongation can be absorbed.

A semiconductor device according to the present invention comprises: a semiconductor element having electrodes on one surface; metal wiring connected to said electrodes via metal bumps, an insulating resin disposed between said semiconductor element and said metal wiring; and concave portions provided in the insulating resin, within which free ends of external terminals of the metal wiring project.

The abovementioned semiconductor device is electrically connected to a mounting substrate via solder balls. In this condition, when the semiconductor device and the mounting substrate are exposed to heat, the semiconductor device and the mounting substrate entirely expand, and elongate in the horizontal direction and vertical direction, respectively. The vertical elongation hardly causes a change in the relative positional relationship between the semiconductor device and the mounting substrate. The horizontal elongation causes a shearing force on the solder balls which electrically connect the semiconductor device and the mounting substrate.

The free end of the external terminal of the metal wiring of the invention projects within the concave portion of the insulating resin. The free end of the external terminal is not restricted by the insulting resin, and has great freedom within the concave portion. In comparison with the conventional semiconductor device, the free end of the external terminal easily bends. Therefore, even when the solder balls relatively displace with respect to the semiconductor device while being restricted by the mounting substrate, the displacement can be absorbed by deformation of the free end of the external terminal.

Even when relative displacement occurs between the semiconductor device and the mounting substrate due to the difference in the coefficient of thermal expansion, the external terminal of the wiring relatively follows the displacement, so that breakage of the connection between the metal wiring and the solder balls rarely occurs. Therefore, even when heat is repeatedly applied to the semiconductor device and the mounting substrate, a conduction failure due to breakage of the connection is suppressed, whereby reliability of the semiconductor device is improved.

In the abovementioned semiconductor device, it is preferable that the external terminal projects within the concave portion. Since the metal wiring is formed by plating exclusively, its strength is not high. Therefore, if the external terminal protrudes from the concave portion, after finishing the semiconductor device as one product, there is a possibility that the external terminal is damaged when the semiconductor device is handled.

By constructing the semiconductor device so that the external terminals project within concave portions without protruding from the outer hull of the semiconductor device, the external terminals are prevented from being damaged or deformed by contact. Therefore, proper postures and forms of the external terminals are guaranteed. Thereby, in the step of electrically connecting the semiconductor device to a mounting substrate by using solder balls, connection with high reliability can be achieved.

In the semiconductor device, it is preferable that the external terminals are provided with solder ball connecting lands, and the external terminal is composed of a base end portion projecting from the inner surface of the concave portion, and a bending portion continuing from this base end portion and extending to the land in a direction anisotropic to the base end portion.

As mentioned above, when the semiconductor device and the mounting substrate are exposed to heat, the semiconductor device and the mounting substrate entirely expand, and elongate in the horizontal direction and vertical direction, respectively. This causes a change in the relative positional relationship between the semiconductor device and the mounting substrate. The base end portion and the solder ball connecting land that are adjacent to each other on the inner surface of the concave portion are connected by the bending portion. Therefore, the base end portion elongates together with the semiconductor device, and the land elongates together with the mounting substrate via the solder ball.

When relative displacement occurs due to a difference in the coefficient of thermal expansion in a condition where the semiconductor device is connected to the mounting substrate via the solder balls, the lands accompany the mounting substrate. Relative displacement between the base end portion and the land is absorbed by deformation of the bending portion. Thereby, an unfavorable force can be prevented from acting on the connecting position between the semiconductor device and the solder ball and the connecting position between the mounting substrate and the solder ball. Therefore, even when heat is repeatedly applied to the semiconductor device and the mounting substrate, a conduction failure due to breakage of the connections is suppressed, and reliability of the semiconductor device is improved.

The bending portion of the external terminal has a function for absorbing relative displacement between the semiconductor device and the mounting substrate. In order to perform this function, the bending portion can be two-dimensionally or three-dimensionally bent.

By constructing the external terminal so that the bending portion can bend in two-dimensional directions of the semiconductor device, when relative displacement occurs between the semiconductor device and the mounting substrate, the external terminal easily absorbs displacement in a direction different from the extending direction of the external terminal from the concave portion. Of course, depending on the shape of the bending portion, even a bending portion which two-dimensionally bends can absorb displacement in the extending direction of the external terminal from the inner surface of the concave portion.

On the other hand, by constructing the external terminal so as to bend in three-dimensional directions of the semiconductor device, in a case where relative displacement occurs between the semiconductor device and the mounting substrate, displacement in the extending direction of the external terminal from the inner surface of the concave portion can be easily absorbed by the external terminal.

In the semiconductor device, it is preferable that a solder resist for protecting the metal wiring is formed on the back surface of the semiconductor device while leaving out the concave portions.

When the metal wiring is exposed to the insulating resin, there is a possibility that the metal wiring is damaged. The solder resist protects the exposed metal wiring, and in addition, prevents the wiring from separating from the insulating resin. By forming a solder resist on the back surface while leaving out the concave portions, the metal wiring can be protected and prevented from separating while maintaining freedom of the external terminals.

In a case where the metal wiring is formed very close to the back surface of the insulating resin, when a solder resist is formed on the back surface of the semiconductor device, the external terminals of the metal wiring sink from the exposed surface of the solder resist. Thereby, the external terminals are prevented from being damaged or deformed by contact, and the correct postures and forms are guaranteed.

### BRIEF DESCRIPTION OF THE DRAWINGS

FIG. 1A through FIG. 1G are sectional views showing a conventional semiconductor device manufacturing method in the order of the steps;

FIG. 2A through FIG. 2N are sectional views showing a semiconductor manufacturing method relating to a first embodiment of the invention in the order of the steps;

FIG. 3 is a partial enlarged sectional view of the semiconductor device of the embodiment;

FIG. 4 is a perspective view of the semiconductor device of FIG. 3 when being viewed from the back surface side;

FIG. 5A through FIG. 5P are sectional views of a semiconductor device manufacturing method relating to a second embodiment of the invention in the order of the steps;

FIG. 6A through FIG. 60 are sectional views showing a semiconductor device manufacturing method relating to a third embodiment of the invention in the order of the steps;

FIG. 7A through FIG. 7P are sectional views showing a semiconductor device manufacturing method relating to a fourth embodiment of the invention in the order of the steps;

FIG. 8A through FIG. 8F are drawings showing modified examples of the external terminal; and

FIG. 9 is a sectional view showing a modified example of the external terminal.

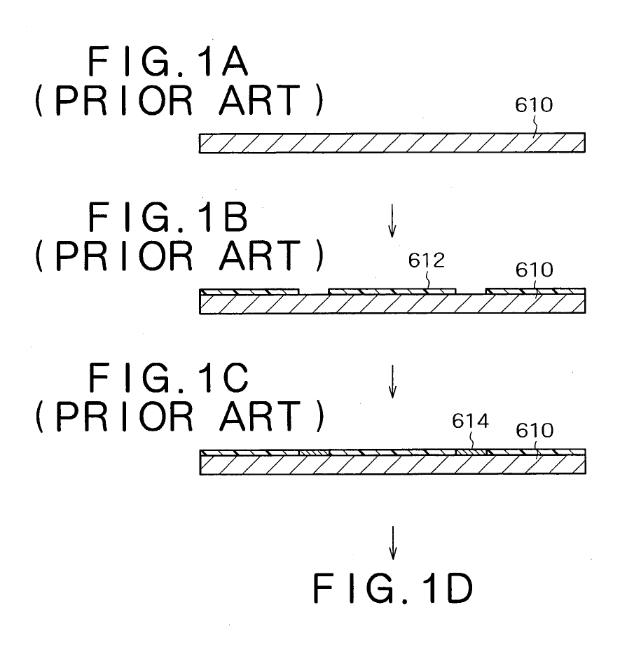

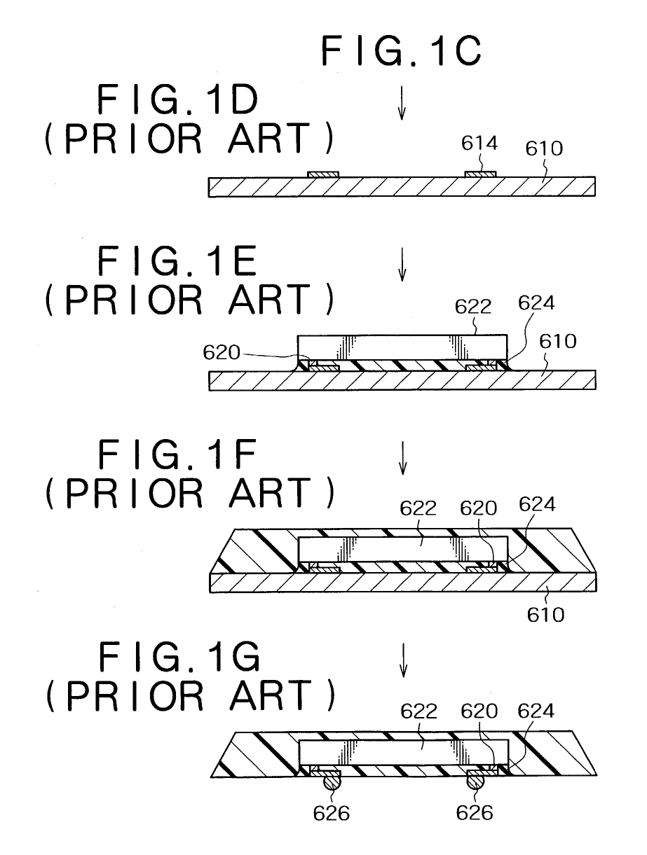

### DETAILED DESCRIPTION OF THE PREFERRED EMBODIMENTS

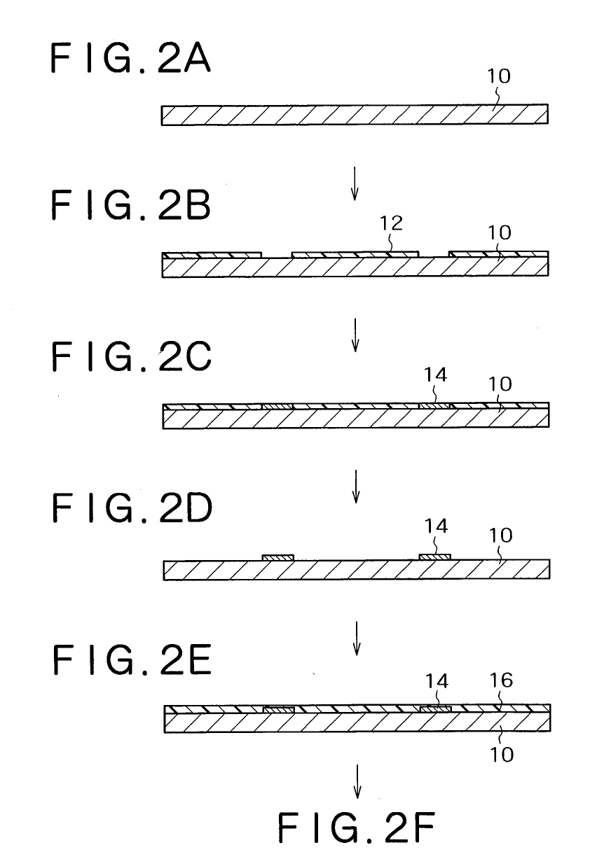

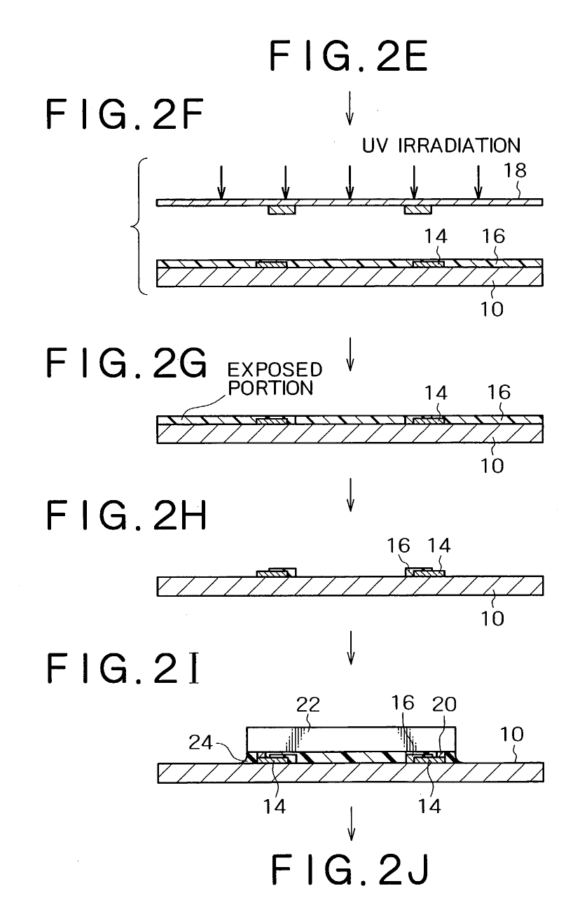

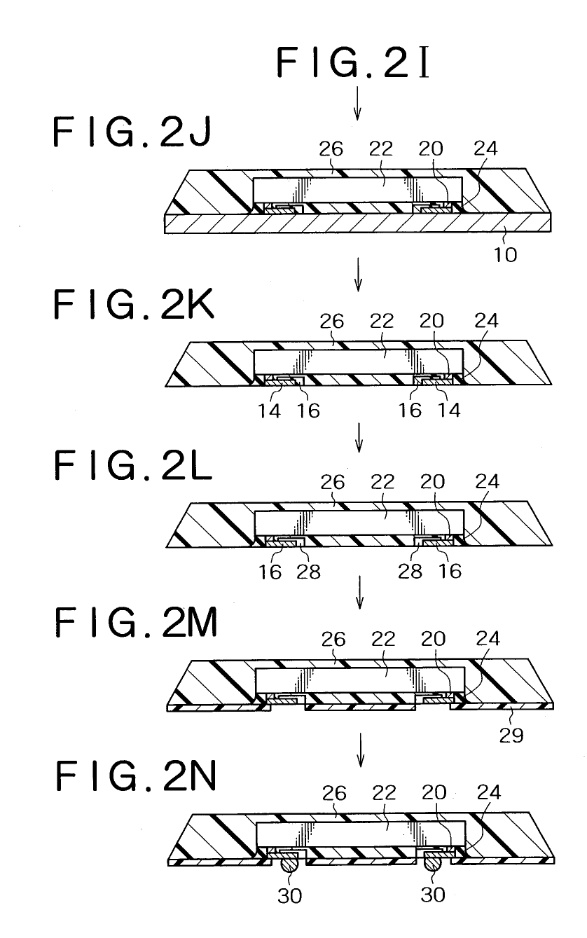

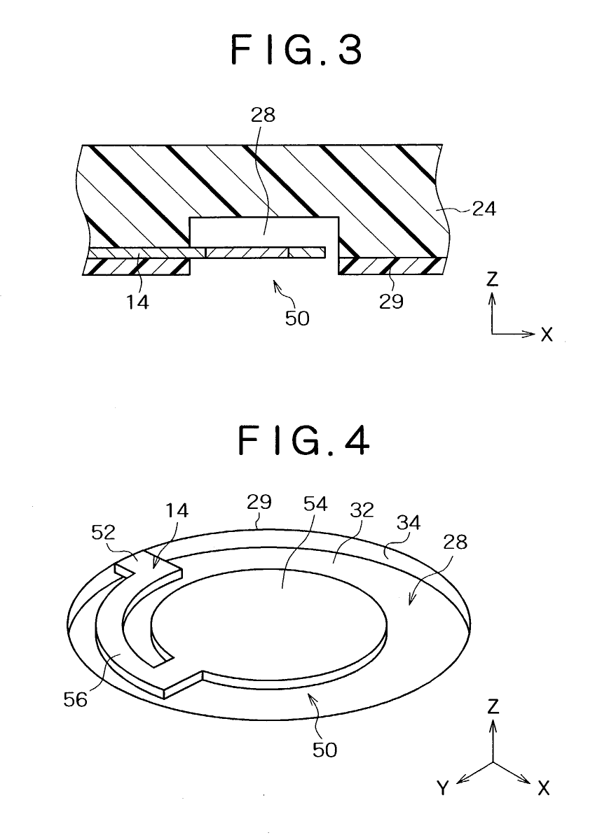

Hereinafter, preferred embodiments of a semiconductor device and a manufacturing method for the same according to the present invention will be described in detail with reference to the accompanying drawings. FIG. 2A through FIG. 2N are sectional views showing a method for manufacturing a semiconductor device relating to a first embodiment of the invention in the order of the steps. FIG. 3 and FIG. 4 are a sectional view and a perspective view with a partially enlarged back surface of a semiconductor device that is manufactured by the abovementioned method, respectively.

As shown in FIG. 2A, a base metal 10 is prepared. The base metal 10 is, for example, a copper plate. Then, as shown in FIG. 2B, a pattern forming resist 12 is applied in a pattern opposite to a metal wiring pattern. Next, as shown in FIG. 2C, metal-plating is applied into grooves formed by the pattern forming resist 12. For this metal, a metal the etching rate of which is lower than that of copper of the material of the base metal 10 is used, namely, the etching ratio is larger. As such a metal, nickel (Ni) is generally used, however, a metal such as gold may be used. Thereafter, after the pattern forming resist 12 is removed, as shown in FIG. 2D, a pattern of metal wiring 14 made from nickel is formed on the base metal 10.

Next, as shown in FIG. 2E, a resist 16 is formed to cover the surface of the base metal 10 and the surface of the metal wiring 14. The resist 16 is formed to a thickness completely covering the metal wiring 14.

Then, as shown in FIG. 2F, the resist 16 is irradiated by ultraviolet rays by using a photo mask 18. In the photo mask 18, a portion to be irradiated by ultraviolet rays is masked. The portion to be irradiated by ultraviolet rays is a portion surrounding the external terminals at positions corresponding to the external terminals of the metal wiring. In FIG. 2G, the portion irradiated by ultraviolet rays is shown.

Next, as shown in FIG. 2H, the resist 16 is removed by development. At a portion which has not been irradiated by ultraviolet rays, the resist 16 remains. The remaining resist 16 covers the external terminal of the metal wiring 14 on the surface of the base metal 10.

Then, as shown in FIG. 2I, electrodes of the semiconductor element 22 and the metal wiring 14 are electrically connected to each other via metal bumps 20. Furthermore, an insulating resin is poured between the surface of the base metal 10 and the back surface of the semiconductor element 22, and the back surface of the semiconductor element 22 is sealed by the insulating resin 24 while including the metal wiring 14 and the resist 16. The insulating resin 24 is formed to be thicker than the resist 16. Therefore, the insulating resin 24 is also formed on the surface of the resist 16.

Next, as shown in FIG. 2J, the semiconductor element 22 is sealed by a sealing resin 26 on the base metal 10, and as shown in FIG. 2K, the base metal 10 is removed by a solvent. After these steps, on the back surface of the insulating resin 24, the metal wiring 14 is exposed. Furthermore, the resist 16 surrounding the external terminals of the metal wiring 14 is exposed.

Next, after the resist 16 is removed, as shown in FIG. 2L, concave portions 28 are formed in the back surface of the insulating resin 24, and the external terminals of the metal wiring 14 are separated from the insulating resin 24. Thereafter, as shown in FIG. 2M, on the back surfaces of the insulating resin 24 and the sealing resin 26, a solder resist 29 is formed by printing while leaving out the concave portions 28. Then, as shown in FIG. 2N, the external terminals of the metal wiring 14 are electrically connected to a mounting substrate (not shown) via solder balls 30.

FIG. 3 and FIG. 4 are a sectional view and a perspective view with a partially enlarged back surface of the semiconductor device manufactured by the above-mentioned method, respectively.

Around the external terminal of the metal wiring 14, a concave portion 28 having a shape corresponding to the remaining resist 16 is formed. In the present embodiment, the resist 16 is formed to be cylindrical, whereby the concave portion 28 is also formed into a cylindrical shape having an inner surface composed of a bottom surface 32 and a side surface 34. The insulating resin 24 is formed to be thicker than the resist 16 in the abovementioned step, the semiconductor element is prevented from being exposed to the bottom surface 28 of the concave portion 28. It is not always necessary that the concave portion 28 is shaped to be cylindrical, and it may be a hollow portion for spacing the external terminal of the metal wiring 14 from the insulating resin 24.

In this concave portion 28, the external terminal 50 of the metal wiring 14 projects from the side surface of the concave portion 28. The external terminal 50 is composed of a base end portion 52 immediately after the projection from the side surface of the concave portion 28, a disk-shaped land 54 to be electrically connected to a solder ball 30, and a bending portion 56 for connecting the base end portion 52 and the outer edge of the land 54. Therefore, the land 54 is supported at one end via the bending portion 56. By thus constructing the external terminal 50, no matter which of X, Y, and Z directions the solder ball 30 to be connected to the land 54 displaces in, the land 54 can displace by following the displacement of the solder ball 30 without restriction.

Furthermore, in the present embodiment, the external terminal 50 is formed in parallel to the insulating resin 24 and the solder resist 29. Therefore, the external terminal 50 is disposed within the concave portion 24 without contact with the bottom surface 32 of the concave portion 28 and without projection to the outside from the exposed surface of the solder resist 29. Furthermore, it is necessary that the external terminal 50 is restricted by peripheral members although it may be in contact with the bottom surface 32.

In the present embodiment, since the external terminal 50 is disposed within the concave portion 28, when the semiconductor device itself is handled, problems such as damage and deformation of the external terminal 50 are suppressed.

Of course, if only followability of the solder ball 30 is considered, it is allowed that the external terminal 50 protrudes from the concave portion 28.

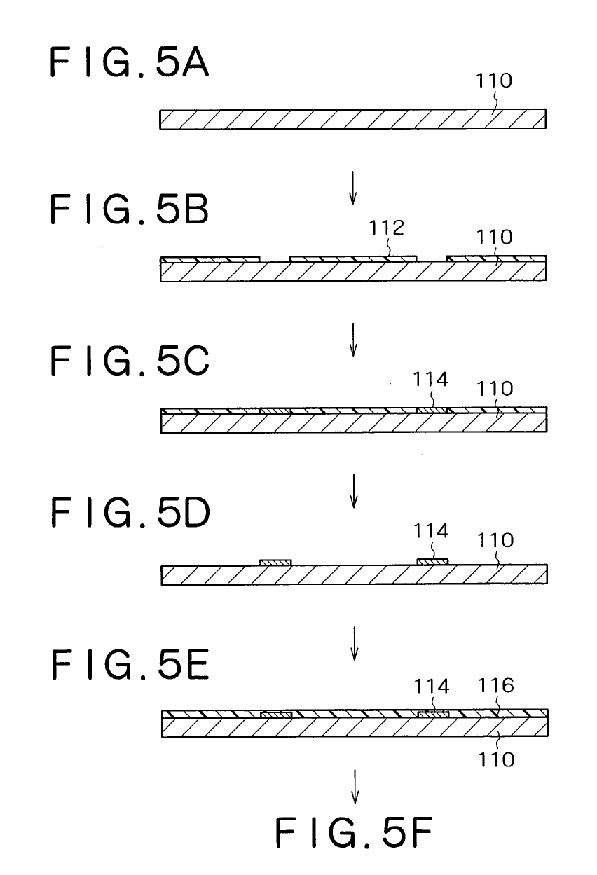

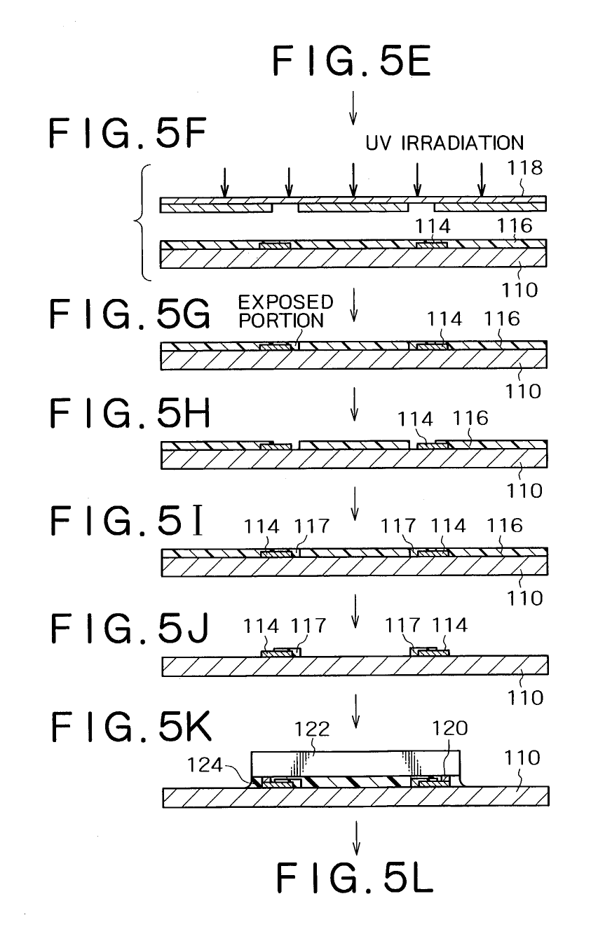

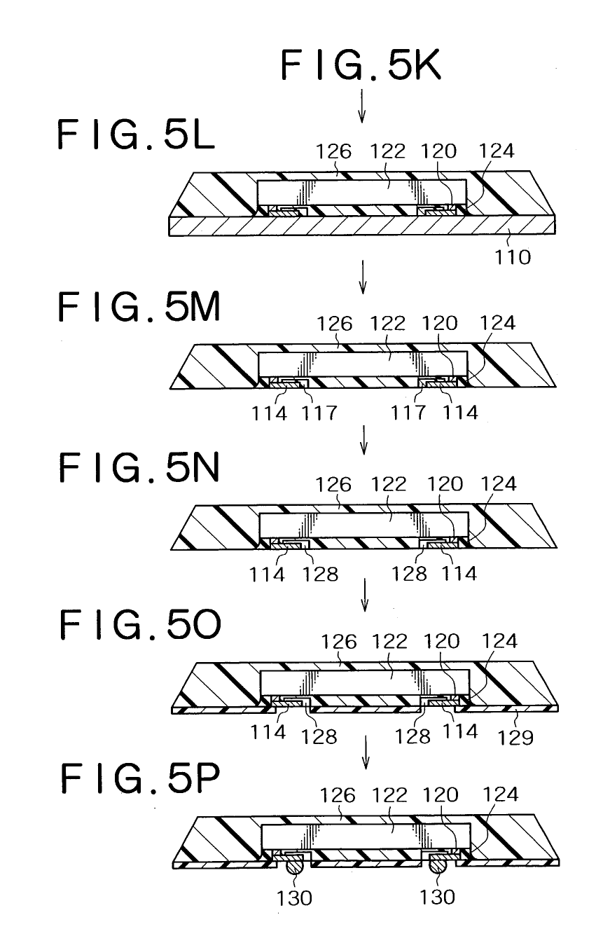

Next, a second embodiment of the invention will be described with reference to FIG. 5A through FIG. 5P. FIG. 5A through FIG. 5P are sectional views showing a semiconductor device manufacturing method relating to a second embodiment of the invention in the order of the steps.

As shown in FIG. 5A through FIG. 5D, a pattern forming resist 112 is applied onto the base metal 110 so as to be opposite to the metal wiring pattern, and metal plating is applied into grooves. Then, after the pattern forming resist 112 is removed, a pattern of the metal wiring 114 is formed on the base metal 110.

Next, as shown in FIG. 5E, a resist 116 is formed to cover the surface of the base metal 110 and the surface of the metal wiring 114. The resist 116 is formed to a thickness completely covering the metal wiring 114.

Then, as shown in FIG. 5F, the resist 116 is irradiated by ultraviolet rays by using a photo mask 118. In the photo mask 118, portions to be shielded from ultraviolet rays are masked. A portion to be irradiated by ultraviolet rays is a portion surrounding the external terminals at positions corresponding to the external terminals of the metal wiring. FIG. 5G shows the portion irradiated by ultraviolet rays.

Next, as shown in FIG. 5H, the exposed resist 116 is removed by development. The resist 116 remains at portions shielded from ultraviolet rays. The resist 116 remains on the surface of the base metal 10 while leaving out the external terminals of the metal wiring 14.

Then, as shown in FIG. 5I, a removing resin 117 is filled onto the external terminals. The portions to be filled with the removing resin 117 are portions at which the resist 116 has been removed by development. Concave portions are formed in the future at portions filled with the removing resin 117. Thereafter, as shown in FIG. 5J, the resist 116 is completely removed from the base metal 110. In this condition, the removing resin 117 covers the external terminals of the metal wiring 114 on the base metal 110.

Next, as shown in FIG. 5K, electrodes of the semiconductor element 122 and the metal wiring 114 are electrically connected via metal bumps 120. Furthermore, an insulating resin 124 is poured between the surface of the base metal 110 and the back surface of the semiconductor element 122, and the back surface of the semiconductor element 122 is sealed by the insulating resin 124 while including the metal wiring 114 and the removing resin 117. The insulating resin 124 is formed to be thicker than the removing resin 117. Therefore, the insulating resin 124 is also formed on the surface of the removing resin 117.

Next, as shown in FIG. 5L, the semiconductor element 122 is sealed on the base metal 110, and as shown in FIG. 5M, the base metal 110 is removed by a solvent. After these steps, the metal wiring 114 is exposed to the back surface of the insulating resin 124. Furthermore, the removing resin 117 surrounding the external terminals of the metal wiring 114 is exposed.

Then, after the removing resin 117 is removed, as shown in FIG. 5N, concave portions 128 are formed in the back surface of the insulating resin 124 to separate the external terminals of the metal wiring 114 from the insulating resin 124. Thereafter, as shown in FIG. 50, on the back surfaces of the insulating resin 124 and the sealing resin 126, a solder resist 129 is formed by means of printing while leaving out the concave portions 128. Next, as shown in FIG. 5P, the external terminals of the metal wiring 114 are electrically connected to a mounting substrate (not shown) via the solder balls 130.

Also in the abovementioned second embodiment, the external terminals of the metal wiring 114 have free ends within the concave portions 128. The shapes of the external terminals are also formed so as to absorb relative displacement between the semiconductor device and the mounting substrate.

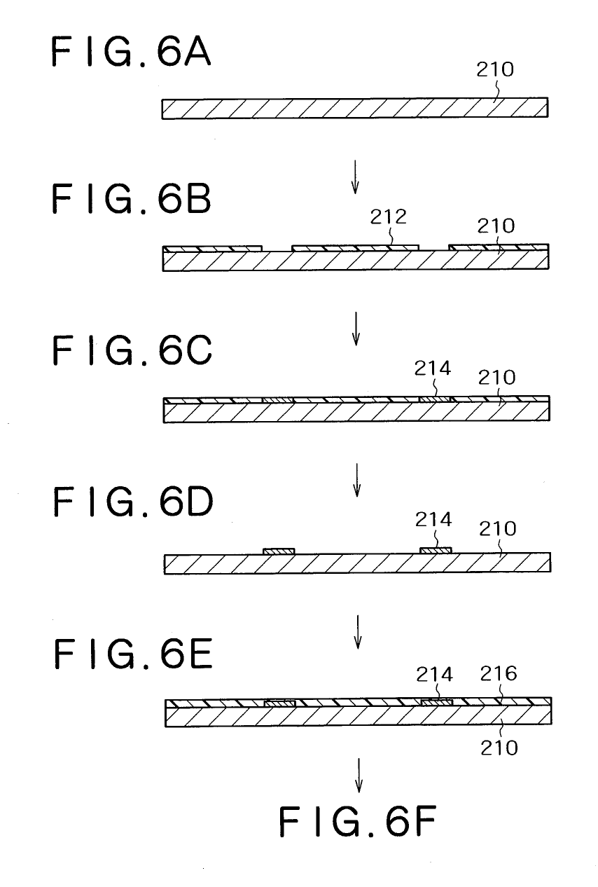

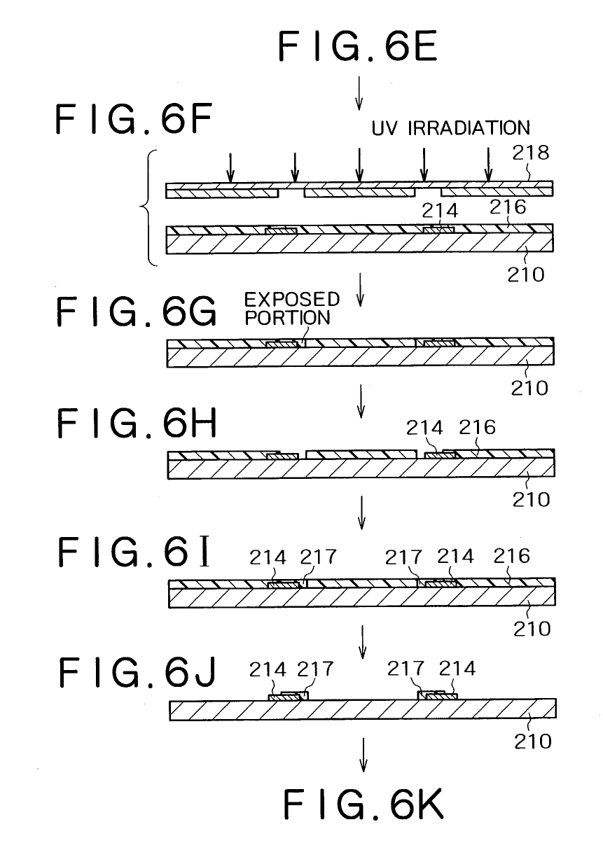

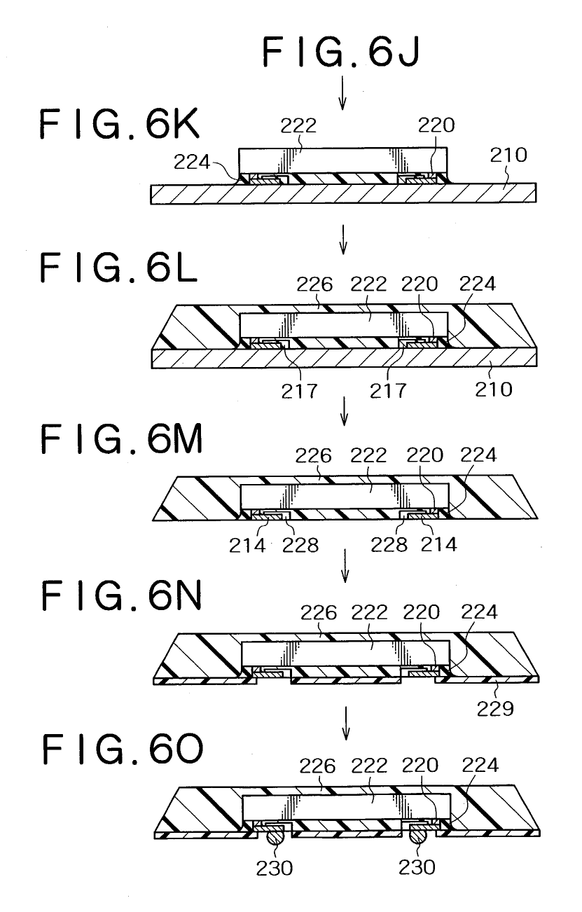

Next, with reference to FIG. 6A through FIG. 60, a semiconductor device manufacturing method relating to a third embodiment of the invention will be described.

As shown in FIG. 6A, a base metal 210 is prepared. The base metal 210 is a copper plate. Then, as shown in FIG. 6B, a pattern forming resist 212 is applied to be opposite to a metal wiring pattern. Then, as shown in FIG. 6C, metal plating is applied into grooves formed by the pattern forming resist 212. Plating is carried out by using a metal other than copper, for example, nickel. Thereafter, after the pattern forming resist 212 is removed, as shown in FIG. 6D, a pattern of metal wiring 214 is formed on the base metal 210.

Next, as shown in FIG. 6E, a resist 216 is formed to cover the surface of the base metal 210 and the surface of the metal wiring 214. The resist 216 is formed to a thickness completely covering the metal wiring 214.

Next, as shown in FIG. 6F, the resist 216 is irradiated by ultraviolet rays by using a photo mask 218. In the photo mask 218, portions to be shielded from ultraviolet rays are masked. A portion to be irradiated by ultraviolet rays is a portion surrounding the external terminals at positions corresponding to the external terminals of the metal wiring. In FIG. 6G, the portion irradiated by ultraviolet rays is shown.

Next, as shown in FIG. 6H, the resist 216 is removed by development. The resist 216 remains at the portions shielded from ultraviolet rays. The resist 216 remains on the surface of the base metal 21 while leaving out the external terminals of the metal wiring 214.

Then, as shown in FIG. 6I, copper plating 217 that is the same metal as the base metal 210 is applied onto the external terminals. Portions to be filled with the copper plating 217 are portions at which the resist 216 has been removed by development. Concave portions are formed in the future at the portions filled with copper plating 217. Thereafter, as shown in FIG. 6J, the resist 216 is completely removed from the base metal 210. In this condition, the copper plating 217 covers the external terminals of the metal wiring 214 on the base metal 210.

Next, as shown in FIG. 6K, electrodes of a semiconductor element 222 and the metal wiring 214 are electrically connected via metal bumps 220. Furthermore, an insulating resin 224 is poured between the surface of the base metal 210 and the back surface of the semiconductor element 222, and the back surface of the semiconductor element 222 is sealed by the insulating resin 224 while including the metal wiring 214 and the copper plating 217. The insulating resin 224 is formed to be thicker than the copper plating 217. Therefore, the insulating resin 224 is also formed on the surface of the copper plating 217.

Next, as shown in FIG. 6L, the semiconductor element 222 is sealed on the base metal 210 by a sealing resin 226. Thereafter, etching is carried out by using a cupric sulfate solution or a cupric chloride solution. By this etching step, the base metal 210 made from copper and the copper plating 217 are simultaneously removed.

After the base metal 210 and the copper plating 217 are removed, as shown in FIG. 6M, concave portions 228 are formed in the back surface of the insulating resin 224 to separate the external terminals of the metal wiring 214 from the insulating resin 224. Thereafter, as shown in FIG. 6N, a solder resist 229 is formed by printing on the back surfaces of the insulating resin 224 and the sealing resin 226 while leaving out the concave portions 228. Then, as shown in FIG. 60, the external terminals of the metal wiring 214 are electrically connected to a mounting substrate (not shown) via solder balls 230.

Also in the abovementioned third embodiment, the external terminals of the metal wiring 214 have free ends within the concave portions 228. The shape of the external terminal is also formed so as to absorb relative displacement between the semiconductor device and the mounting substrate.

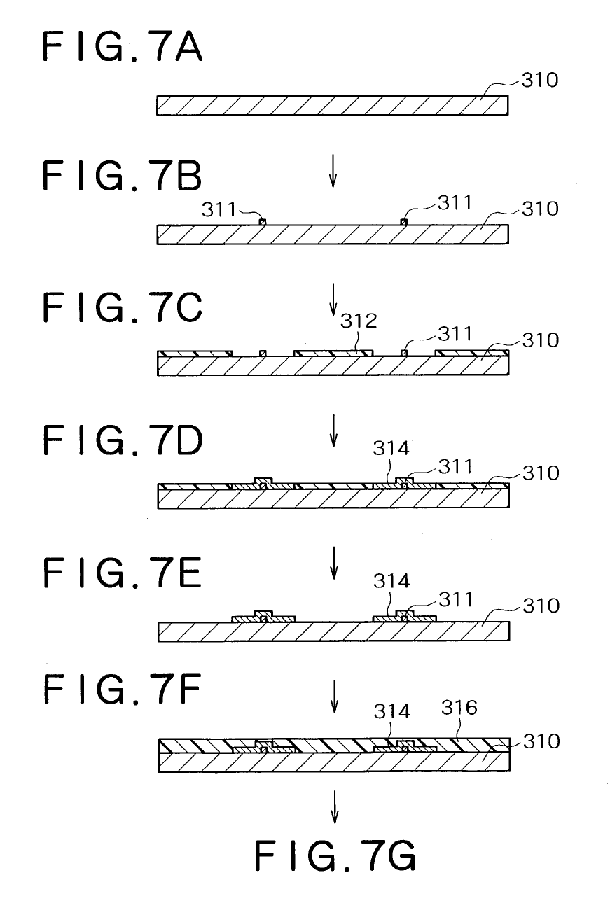

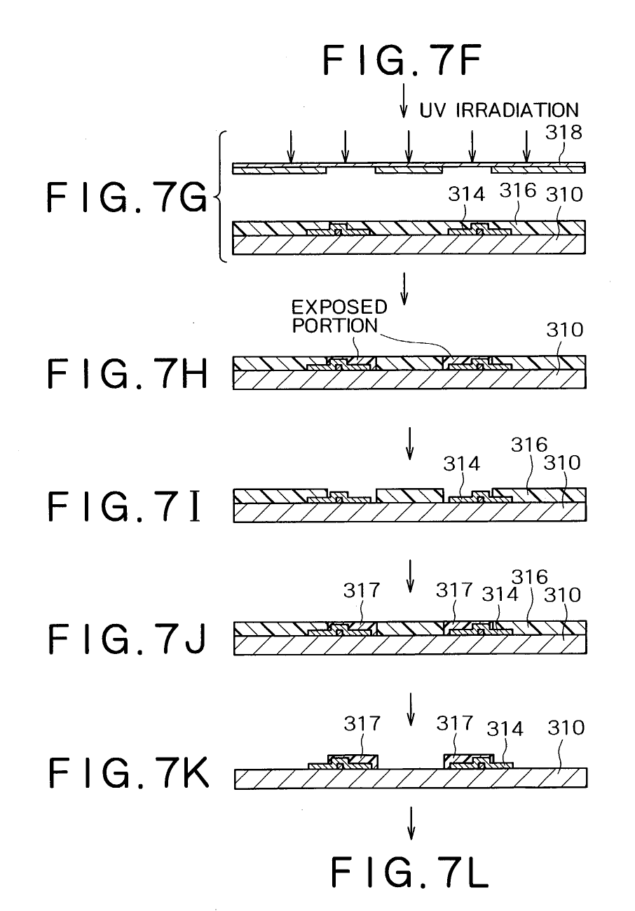

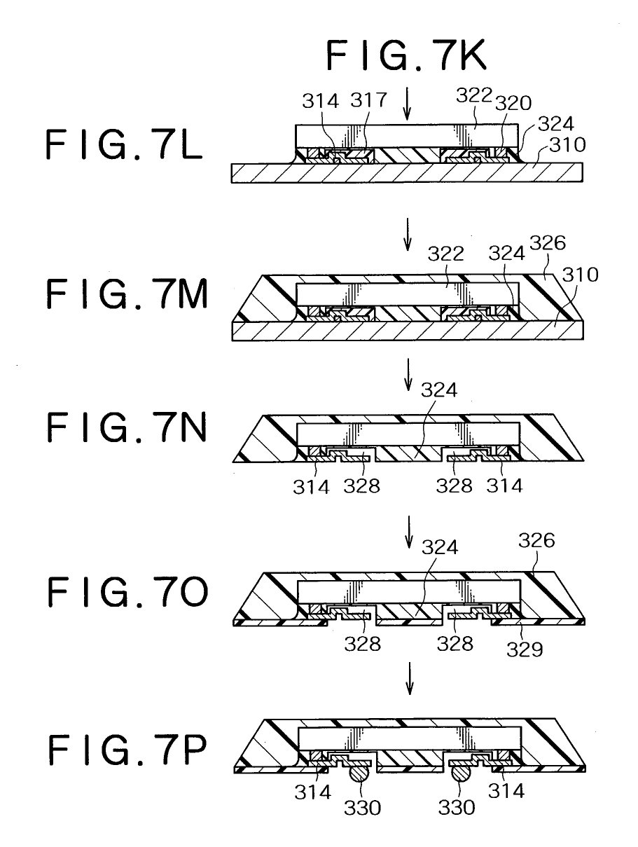

Next, with reference to FIG. 7A through FIG. 7P, a semiconductor device manufacturing method relating to a fourth embodiment of the invention will be described.

As shown in FIG. 7A, a base metal 310 is prepared. The base metal 310 is a copper plate. Then, as shown in FIG. 7B, on the base metal 310, convex portions 311 are formed near the base end portions that serve as free ends of the external terminals when the device is finished as a product. In the present embodiment, the convex portions 311 are made from copper that is the same as the base metal 310, however, it may be formed from a removing resin as in the second embodiment. However, in the case where the removing resin is used, a step for dissolving the resin is added, so that formation of the convex portions 311 from the same metal as the base metal 310 is preferable. In addition, it is also possible that irregular portions 311 are formed at predetermined portions in the step of preparation of the base metal 310.

Next, as shown in FIG. 7C, a pattern forming resist 312 is applied to be opposite to a metal wiring pattern. Then, as shown in FIG. 7D, metal plating is applied into grooves formed by the pattern forming resist 312. Plating is carried out by using a metal other than copper, for example, nickel. Then, after the pattern forming resist 312 is removed, as shown in FIG. 7E, a pattern of metal wiring 314 is formed on the base metal 310. After this step, the metal wiring 314 crosses the convex portions 311 near the base end portions that serve as free ends of the external terminals when the semiconductor device is finished as a product.

Next, as shown in FIG. 7F, a resist 316 is formed to cover the surface of the base metal 310 and the surface of the metal wiring 314. The resist 316 is formed to a thickness completely covering the metal wiring 314.

Next, as shown in FIG. 7G, the resist 316 is irradiated by ultraviolet rays by using a photo mask 318. In the photo mask 318, portions to be shielded from ultraviolet rays are masked. A portion to be irradiated by ultraviolet rays is a portion surrounding the external terminals at positions corresponding to the external terminals of the metal wiring. In FIG. 7H, a portion irradiated by ultraviolet rays is shown.

Then, as shown in FIG. 7I, the resist 316 is removed by development. The resist 316 remains at the portions shielded from ultraviolet rays. The resist 316 remains on the surface of the base metal 310 while leaving out the external terminals of the metal wiring 314.

Next, as shown in FIG. 7J, copper plating 317 that is the same metal as the base metal 310 and the convex portions 311 is applied onto the external terminals. The portions to be filled with the copper plating 317 are the portions at which the resist 316 has been removed by development. Concave portions are formed in the future at the portions filled with the copper plating 317.

Thereafter, as shown in FIG. 7K, the resist 316 is completely removed from the base metal 310. In this condition, the copper plating 317 covers the external terminals of the metal wiring 314 on the base metal 310.

Next, as shown in FIG. 7L, electrodes of a semiconductor element 322 and the metal wiring 314 are electrically connected via metal bumps 320. Furthermore, an insulating resin 324 is poured between the surface of the base metal 310 and the back surface of the semiconductor element 322, and the back surface of the semiconductor element 322 is sealed by the insulating resin 324 while including the metal wiring 314 and the copper plating 317. The insulating resin 324 is formed to be thicker than the copper plating 317. Therefore, the insulating resin 324 is also formed on the surface of the copper plating 317.

Then, as shown in FIG. 7M, the semiconductor element 322 is sealed on the base metal 310 by a sealing resin 326. Thereafter, etching is carried out by using a cupric sulfate solution or a cupric chloride solution. By this step of etching, the base metal made from copper, the convex portions 311 made from copper, and the copper plating 317 are simultaneously removed.

After the base metal 310, convex portions 311, and copper plating 317 are removed, as shown in FIG. 7N, concave portions 328 are formed in the back surface of the insulating resin 324 to separate the external terminals of the metal wiring 314 from the insulating resin 324. In the present embodiment, the convex portions 311 are also simultaneously removed. As a result, the free ends of the external terminals are bent in three-dimensional directions.

Thereafter, as shown in FIG. 70, a solder resist 329 is formed by printing on the back surfaces of the insulating resin 324 and the sealing resin 326 while leaving out the concave portions 328.

Next, as shown in FIG. 7P, the external terminals of the metal wiring 314 are electrically connected to a mounting substrate (not shown) via solder balls 330.

Also in the abovementioned fourth embodiment, the external terminals of the metal wiring 314 have free ends within the concave portions 328. The shape of the external terminal is also formed so as to absorb relative displacement between the semiconductor device and the mounting substrate.

The methods of the abovementioned first through third embodiments are used for exclusively manufacturing a semiconductor device in which the free ends of the external terminals bend in two-dimensional directions. The manufacturing method described in the present embodiment is suitable for a case where free ends that bend in three-dimensional directions are formed as well as the case where free ends that bend in two-dimensional directions are formed.

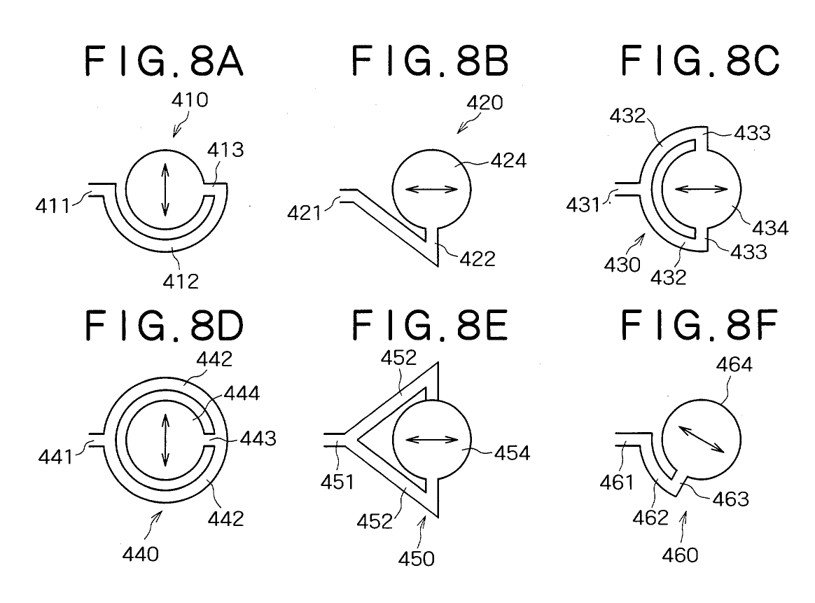

FIG. 8A through FIG. 8F show other examples of the external terminals of the metal wiring. These external terminals have bending portions that bend in two-dimensional directions.

The external terminal 410 shown in FIG. 8A has a bending portion 412 formed into an arc shape extending approximately 180° from the base end portion 411, and a land 414 is supported at the end of the bending portion 412 via a bridge 413. The external terminal 410 thus constructed is suitable for absorption of displacement in the extending direction of the base end portion 411, that is, displacement in the direction orthogonal to the extending direction of the bridge.

The external terminal 420 shown in FIG. 8B has an acute L-shaped bending portion 422 extending from the base end portion 421, and a land 424 is supported at the end of the bending portion 422. The external terminal 420 thus constructed is suitable for absorption of displacement in the extending direction of the base end portion 421.

The external terminal 430 shown in FIG. 8C has a pair of arc-shaped bending portions 432 and 432 extending approximately 90° C. from the base end portion 431, and a land 434 is supported at the ends of the bending portions 432 and 432 via bridges 433. The external terminal 430 thus constructed is suitable for absorption of displacement in the extending direction of the base end portion 431, that is, displacement in the direction orthogonal to the extending directions of the bridges 433.

The external terminal 440 shown in FIG. 8D has a pair of arc-shaped bending portions 442 and 442 extending approximately 180° from the base end portion 441, and the pair of bending portions 442 and 442 form a circle. A land 444 is supported by an inward bridge 43 at a side of the bending portion 442 opposite to the base end portion 441. The external terminal 440 thus constructed is suitable for absorption of displacement in the direction orthogonal to the extending direction of the base end portion 441 and the extending direction of the bridge 443.

The external terminal 450 shown in FIG. 8E has a pair of acute L-shaped bending portions 452 and 452 extending from the base end portion 451, and a land 454 is supported at the front ends of the pair of bending portions 452 and 452. The external terminal 450 thus constructed is suitable for absorption of displacement in the extending direction of the base end portion 451.

The external terminal 460 shown in FIG. 8F has an arc-shaped bending portion 462 extending approximately 45° from the base end portion 461, and has a bridge 463 toward the arc center from the end of the bending portion 462, and a land 464 is supported at the front end of the bridge 463. The external terminal 410 thus constructed is suitable for absorption of displacement in the direction orthogonal to the extending direction of the bridge 463.

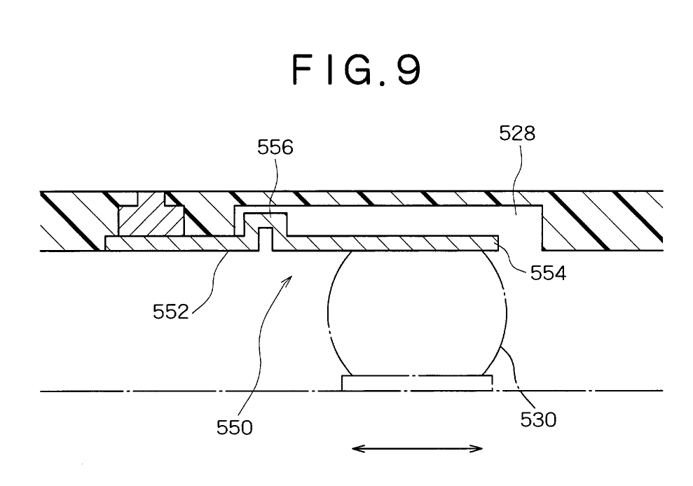

FIG. 9 is a sectional view showing another example of the external terminal of the metal wiring. The external terminal 550 of the metal wiring of this example has a bending portion in a three-dimensional direction of the semiconductor device, that is, in the thickness direction. The semiconductor device shown in FIG. 9 is manufactured exclusively by the method of the fourth embodiment described with reference to FIG. 7A through FIG. 7P.

As shown in FIG. 9, the external terminal 550 projects from the side surface of the concave portion 528 inside the concave portion 528. The external terminal 550 is composed of a base end portion 552 immediately after the projection from the side surface of the concave portion 528, a land 554 to be electrically connected to a solder ball 530, and a bending portion 556 connecting the base end portion 552 and the land 554.

When relative displacement occurs in the direction of the arrows between the semiconductor device and a mounting substrate, the bending portion 556 three-dimensionally deforms and absorbs the displacement. Therefore, the land 554 can deform by following the displacement of the solder ball 550 without restriction by the external terminal 550. The external terminal of this example has great ability to absorb displacement in the direction of projection of the external terminal and the direction perpendicular to the projection.

One semiconductor device has a plurality of external terminals. In the respective terminals, it is expected that displacement directions are different from each other. Preferably, the shapes of the respective external terminals are selected so that the external terminals can displace radially from the semiconductor device, whereby relative displacement between the semiconductor device and a mounting substrate can be more effectively absorbed.

As described in detail above, according to the invention, concave portions are formed in the back surface of the insulating resin, and free ends of the external terminals are made to project within the concave portions. Even when relative displacement occurs due to a difference in the coefficient of thermal expansion between the semiconductor device and the mounting substrate, the displacement is absorbed by deformation of the free ends of the external terminals within the concave portions, the solder balls accompany the mounting substrate, and an extra force such as a shearing force hardly acts on the connecting portions of the external terminals and the solder balls. Therefore, even if the semiconductor device is repeatedly exposed to heat, deterioration hardly occurs at the connecting portions between the semiconductor device and the mounting substrate, the life of the semiconductor device is extended, and the reliability of the product is improved.

What is claimed is:

1. A semiconductor device comprising:
a semiconductor element having electrodes on one surface;
metal wiring connected to said electrodes via metal bumps,
an insulating resin disposed between said semiconductor element and said metal wiring; and
concave portions provided in said insulating resin, within which free ends of external terminals of the metal wiring project.

2. The semiconductor device according to claim 1, wherein said external terminals project within said concave portions.

3. The semiconductor device according to claim 2, wherein said external terminal is composed of a base end portion projecting within the concave portion, a solder ball connecting land disposed within the concave portion, and a bending portion that is disposed within the concave portion and bends and extends in a direction different from the direction of projection of said base end portion to be connected to said land.

4. The semiconductor device according to claim 3, wherein said bending portion extends and bends in a direction parallel to the plane of the semiconductor device.

5. The semiconductor device according to claim 3, wherein said bending portion extends and bends in a direction perpendicular to the plane of the semiconductor device.

6. The semiconductor device according to claim 1, wherein a solder resist for protecting metal wiring is formed on said one surface of the semiconductor device while leaving out the concave portions.

7. A manufacturing method for a semiconductor device comprising the steps of:
forming a metal wiring pattern on the surface of a base metal;
forming a resist on said base metal and said metal wiring;
removing said resist while leaving out external terminals of the metal wiring;
electrically connecting electrodes of a semiconductor element and the wiring via metal bumps;
sealing the wiring and the resist by an insulating resin between the surface of the base metal and the back surface of the semiconductor element;
sealing the semiconductor element on the base metal by a sealing resin;
removing the base metal; and
removing the resist.

8. A manufacturing method for a semiconductor device comprising the steps of:
forming a metal wiring pattern on the surface of a base metal;
forming a resist on said base metal and said metal wiring;
removing said resist on external terminals of the metal wiring;
filling a removing resin on the external terminals of the metal wiring;
removing the resist;
electrically connecting electrodes of a semiconductor element and the wiring via metal bumps;
sealing the wiring and the resist by an insulating resin between the surface of the base metal and the back surface of the semiconductor element;
sealing the semiconductor element by a sealing resin on the base metal;
removing the base metal; and
removing said removing resin.

9. A manufacturing method for a semiconductor device comprising the steps of:
forming a wiring pattern of a metal other than copper on the surface of a base metal that is formed from copper;
forming a resist on said base metal and said metal wiring;
removing said resist on external terminals of the metal wiring;
copper-plating on the external terminals of the metal wiring;
removing the resist;
electrically connecting electrodes of a semiconductor element and the wiring via metal bumps;
sealing the wiring and the resist by an insulating resin between the surface of the base metal and the back surface of the semiconductor element;
sealing the semiconductor element by a sealing resin on the base metal; and
simultaneously removing the base metal and copper plating.

10. The manufacturing method for a semiconductor device according to claim 9, wherein said metal other than copper is a metal the etching rate of which is lower than that of copper.

11. The manufacturing method for a semiconductor device according to claim 7, further comprising, prior to the forming of a metal wiring pattern, a step of forming irregular portions at the positions of said external terminals on the surface of the base metal, and the forming of a metal wiring pattern is to form a metal wiring pattern crossing said irregular portions.

12. The manufacturing method for a semiconductor device according to claim 8, further comprising, prior to the forming of a metal wiring pattern, a step of forming irregular portions at the positions of said external terminals on the surface of the base metal, and the forming of a metal wiring pattern is to form a metal wiring pattern crossing said irregular portions.

13. The manufacturing method for a semiconductor device according to claim 9, further comprising, prior to the forming of a metal wiring pattern, a step of forming irregular portions at the positions of said external terminals on the surface of the base metal, and the forming of a metal wiring pattern is to form a metal wiring pattern crossing said irregular portions.

14. The manufacturing method for a semiconductor device according to claim 7, further comprising a step of coating said sealing resin, insulating resin, and metal wiring with a solder resist while leaving out said external terminals.

15. The manufacturing method for a semiconductor device according to claim 8, further comprising a step of coating said sealing resin, insulating resin, and metal wiring with a solder resist while leaving out said external terminals.

16. The manufacturing method for a semiconductor device according to claim 9, further comprising a step of coating said sealing resin, insulating resin, and metal wiring with a solder resist while leaving out said external terminals.

17. The manufacturing method for a semiconductor device according to claim 10, further comprising a step of coating said sealing resin, insulating resin, and metal wiring with a solder resist while leaving out said external terminals.
